(19) United States
(12) Patent Application Publication
(10) Pub. No.: US 2026/0136806 A1
(43) Pub. Date: May 14, 2026

(54) DISPLAY DEVICE AND MANUFACTURING METHOD OF DISPLAY DEVICE

(71) Applicant: Magnolia White Corporation, Tokyo (JP)

(72) Inventor: Manabu YAMASHITA, Tokyo (JP)

(73) Assignee: Magnolia White Corporation, Tokyo (JP)

(21) Appl. No.: 19/386,287

(22) Filed: Nov. 12, 2025

(30) Foreign Application Priority Data
Nov. 12, 2024 (JP) 2024-197541

(51) Int. Cl. H10K 59/80; H10K 59/12; H10K 59/122; H10K 59/35; H10K 71/60

(52) U.S. Cl. CPC H10K 59/871; H10K 59/1201; H10K 59/122; H10K 59/35; H10K 71/60

(57) ABSTRACT

According to one embodiment, a manufacturing method of a display device includes steps of preparing a processing substrate including a first lower electrode, a second lower electrode, a third lower electrode and a partition having an overhang shape, forming a first stacked film using the partition as a mask, forming a first sealing layer on the first stacked film, forming a first resist on the first sealing layer, patterning the first sealing layer using the first resist as a mask to expose a part of the partition surrounding each of the second lower electrode and the third lower electrode, performing water plasma treatment on the processing substrate, and patterning the first stacked film using the first resist as a mask.

### CROSS-REFERENCE TO RELATED APPLICATIONS

This application is based upon and claims the benefit of priority from Japanese Patent Application No. 2024-197541, filed Nov. 12, 2024, the entire contents of which are incorporated herein by reference.

### FIELD

Embodiments described herein relate generally to a display device and a manufacturing method of a display device.

### BACKGROUND

Recently, display devices with organic light-emitting diodes (OLED) applied thereto as display elements have been put into practical use. Each of these display elements comprises a pixel circuit including a thin-film transistor, a lower electrode connected to the pixel circuit, an organic layer covering the lower electrode, and an upper electrode covering the organic layer. The organic layer includes functional layers such as a hole transport layer and an electron transport layer in addition to a light emitting layer.

The process of manufacturing the display elements demand a technique for suppressing decreases in reliability.

### BRIEF DESCRIPTION OF THE DRAWINGS

FIG. 1 is a view showing an example of a display device DSP.

FIG. 2 is a diagram showing an example of the layout of subpixels SP1, SP2, and SP3 which constitute one pixel PX.

FIG. 3 is a view for describing an example of the pixel PX.

FIG. 4 is a schematic cross-sectional view of the display device DSP along the A-B line of FIG. 2.

FIG. 5A is a view for describing a manufacturing method of the display device DSP.

FIG. 5B is a view for describing the manufacturing method of the display device DSP.

FIG. 5C is a view for describing the manufacturing method of the display device DSP.

FIG. 5D is a view for describing the manufacturing method of the display device DSP.

FIG. 5E is a view for describing the manufacturing method of the display device DSP.

FIG. 5F is a view for describing the manufacturing method of the display device DSP.

FIG. 5G is a view for describing the manufacturing method of the display device DSP.

FIG. 5H is a view for describing the manufacturing method of the display device DSP.

FIG. 5I is a view for describing the manufacturing method of the display device DSP.

FIG. 5J is a view for describing the manufacturing method of the display device DSP.

FIG. 5K is a view for describing the manufacturing method of the display device DSP.

FIG. 5L is a view for describing the manufacturing method of the display device DSP.

FIG. 6 is a diagram for describing main steps for forming display elements DE1, DE2, and DE3 on a processing substrate SUB.

FIG. 7A is a view for describing another manufacturing method.

FIG. 7B is a view for describing the other manufacturing method.

FIG. 7C is a view for describing the other manufacturing method.

FIG. 7D is a view for describing the other manufacturing method.

FIG. 7E is a view for describing the other manufacturing method.

FIG. 8 is a view for describing the other manufacturing method.

### DETAILED DESCRIPTION

An object of the embodiment is to provide a display device capable of suppressing decreases in reliability and a manufacturing method of the display device.

In general, according to one embodiment, a manufacturing method of a display device includes steps of preparing a processing substrate by forming a first lower electrode, a second lower electrode, and a third lower electrode above a substrate and forming a partition having an overhang shape, surrounding each of the first lower electrode, the second lower electrode, and the third lower electrode, forming a first stacked film including a first organic layer, a first upper electrode, and a first cap layer on the first lower electrode, the second lower electrode, and the third lower electrode using the partition as a mask, forming a first sealing layer on the first stacked film, covering the partition with the first sealing layer, forming a first resist patterned into a predetermined shape on the first sealing layer, patterning the first sealing layer using the first resist as a mask to expose a part of the partition surrounding each of the second lower electrode and the third lower electrode, performing water plasma treatment on the processing substrate, patterning the first stacked film using the first resist as a mask to expose the second lower electrode and the third lower electrode, and removing the first resist.

According to another embodiment, a display device includes a substrate, an inorganic insulating layer provided above the substrate, a first display element configured to display a first color, a second display element configured to display a second color different from the first color, a third display element configured to display a third color different from the first color and the second color, a partition formed in an overhang shape, provided on the inorganic insulating layer, having conductivity, and surrounding each of the first display element, the second display element, and the third display element, a first sealing layer covering the first display element, a second sealing layer covering the second display element, and a third sealing layer covering the third display element. The partition comprises a bottom layer provided on the inorganic insulating layer, a stem layer provided on the bottom layer, and a top layer provided on the stem layer. Both end portions of each of the bottom layer and the top layer protrude relative to side surfaces of the stem layer. The stem layer has a cavity recessing with respect to the side surface surrounding each of the second display element and the third display element to expose the bottom layer.

Embodiment can provide a display device capable of suppressing decreases in reliability and a manufacturing method of the display device.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as a first direction X. A direction parallel to the Y-axis is referred to as a second direction Y. A direction parallel to the Z-axis is referred to as a third direction Z. A plan view is defined as appearance when various types of elements are viewed parallel to the third direction Z. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

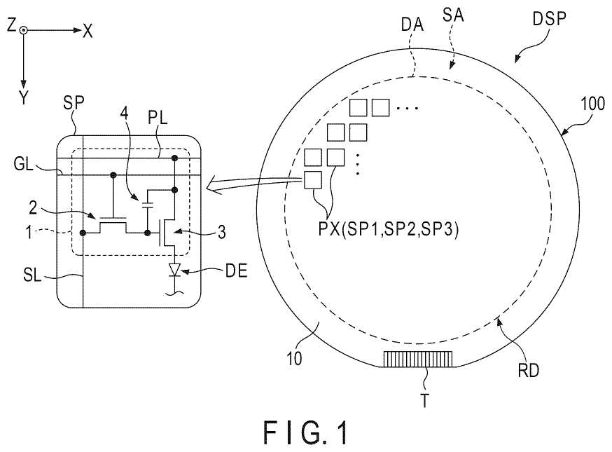

FIG. 1 is a view showing an example of a display device DSP.

The display device DSP comprises a display panel 100. The display panel 100 has a display area DA for displaying images and a surrounding area SA around the display area DA on an insulating substrate 10. The substrate 10 may be either a glass substrate or a resinous substrate having flexibility.

The outer edge of at least a part of the display area DA has a round portion RD. In the illustrated example, the display area DA has a circular shape in plan view. The shape of the display area DA in plan view is not limited to the illustrated example. For example, the outer edge of the display area DA may be constituted by the round portion RD and a straight portion.

The display area DA comprises a plurality of pixels PX arranged in a matrix in the first direction X and the second direction Y. Each pixel PX includes a plurality of subpixels SP that display different colors. For example, each pixel PX includes a subpixel SP1, which displays the first color, a subpixel SP2, which displays the second color, and a subpixel SP3, which displays the third color. The first color, the second color, and the third color are different colors. Each pixel PX may include a subpixel SP, which displays another color such as white in addition to the subpixels SP1, SP2, and SP3 or instead of one of the subpixels SP1, SP2, and SP3.

The round portion RD in the display area DA is a shape in a macroscopic scale. In a microscopic scale, this shape is formed by providing a plurality of pixels PX in a stair step layout.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. One of a source electrode and a drain electrode of the pixel switch 2 is connected to a signal line SL. The other is connected to a gate electrode of the drive transistor 3 and the capacitor 4. In the drive transistor 3, one of a source electrode and a drain electrode is connected to a power line PL and the capacitor 4. The other is connected to the display element DE. In the illustrated example, the scanning line GL and the power line PL extend in the first direction X and the signal line SL extends in the second direction Y.

The configuration of the pixel circuit 1 is not limited to the illustrated example. For example, the pixel circuit 1 may comprise more thin-film transistors and capacitors.

For example, the display element DE is an organic light emitting diode (OLED) as a light emitting element and thus may be called an organic EL element.

The display device DSP further comprises a terminal portion T provided in the surrounding area SA. The terminal portion T comprises a plurality of terminals. For example, the terminal portion T is electrically connected to an IC chip or a flexible printed circuit board for driving the display elements DE.

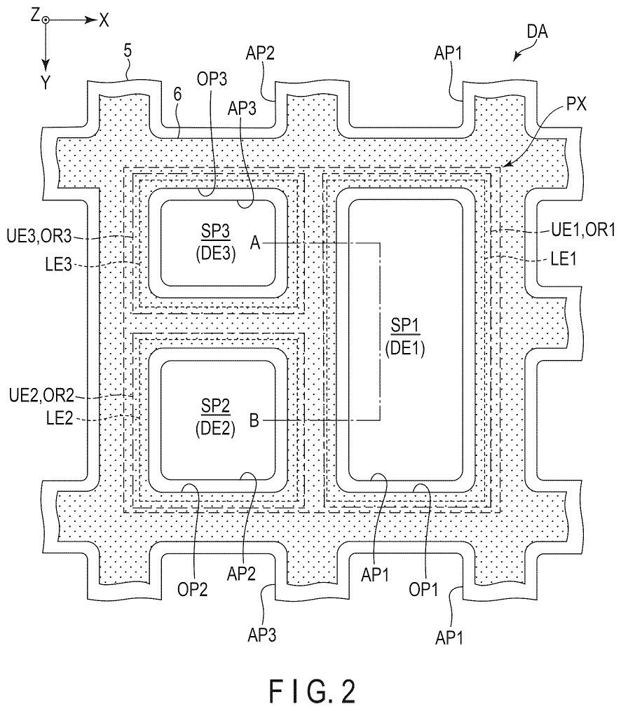

FIG. 2 is a diagram showing an example of the layout of the subpixels SP1, SP2, and SP3 which constitute one pixel PX.

In the illustrated example, the subpixels SP2 and SP3 are arranged in the second direction Y. Further, the subpixels SP1 and SP2 are arranged in the first direction X, and the subpixels SP1 and SP3 are arranged in the first direction X.

When the subpixels SP1, SP2, and SP3 are arranged in this layout, in the display area DA, a column in which the subpixels SP2 and SP3 are alternately arranged in the second direction Y and a column in which the plurality of subpixels SP1 are arranged in the second direction Y are formed. These columns are alternately arranged in the first direction X. The layout of the subpixels SP1, SP2, and SP3 is not limited to the illustrated example.

An inorganic insulating layer 5 and a partition 6 are provided in the display area DA. The inorganic insulating layer 5 has apertures AP1, AP2, and AP3 in the respective subpixels SP1, SP2, and SP3. The inorganic insulating layer 5 having these apertures AP1, AP2, and AP3 may be called a rib.

The partition 6 overlaps the inorganic insulating layer 5 in plan view. The partition 6 is formed into a grating shape surrounding the apertures AP1, AP2, and AP3. That is, the partition 6 has respective apertures OP1, OP2, and OP3 in the respective subpixels SP1, SP2, and SP3 in the same manner as the inorganic insulating layer 5. The aperture OP1 overlaps the aperture AP1. The aperture OP2 overlaps the aperture AP2. The aperture OP3 overlaps the aperture AP3. The partition 6 is conductive and is electrically connected to a terminal with common voltage at the terminal portion T shown in FIG. 1.

The subpixels SP1, SP2, and SP3 comprise respective display elements DE1, DE2, and DE3 as the display elements DE.

The display element DE1 of the subpixel SP1 comprises a lower electrode LE1, an upper electrode UE1, and an organic layer OR1, which overlap the aperture AP1. The peripheral portion of the lower electrode LE1 is covered with the inorganic insulating layer 5. The lower electrode LE1, the organic layer OR1, and the upper electrode UE1, which constitute the display element DE1 are surrounded by the partition 6 in plan view. The peripheral portion of each of the organic layer OR1 and the upper electrode UE1 overlaps the inorganic insulating layer 5 in plan view.

The display element DE2 of the subpixel SP2 comprises a lower electrode LE2, an upper electrode UE2, and an organic layer OR2, which overlap the aperture AP2. The peripheral portion of the lower electrode LE2 is covered with the inorganic insulating layer 5. The lower electrode LE2, the organic layer OR2, and the upper electrode UE2, which constitute the display element DE2 are surrounded by the partition 6 in plan view. The peripheral portion of each of the organic layer OR2 and the upper electrode UE2 overlaps the inorganic insulating layer 5 in plan view.

The display element DE3 of the subpixel SP3 comprises a lower electrode LE3, an upper electrode UE3, and an organic layer OR3, which overlap the aperture AP3. The peripheral portion of the lower electrode LE3 is covered with the inorganic insulating layer 5. The lower electrode LE3, the organic layer OR3, and the upper electrode UE3, which constitute the display element DE3 are surrounded by the partition 6 in plan view. The peripheral portion of each of the organic layer OR3 and the upper electrode UE3 overlaps the inorganic insulating layer 5 in plan view.

In the illustrated example, the outlines of the lower electrodes LE1, LE2, and LE3 are indicated by broken lines, and the outlines of the organic layers OR1, OR2, and OR3 and the upper electrodes UE1, UE2, and UE3 are indicated by short dashed lines. The outlines of the respective lower electrodes, organic layers, and upper electrodes shown in the figure may not reflect the exact shapes.

For example, the lower electrodes LE1, LE2, and LE3 correspond to the anodes of the display elements. The upper electrodes UE1, UE2, and UE3 correspond to the cathodes of the display elements or a common electrode and contact the partition 6.

The lower electrode LE1 is electrically connected to the pixel circuit 1 (refer to FIG. 1) of the subpixel SP1. The lower electrode LE2 is electrically connected to the pixel circuit 1 of the subpixel SP2. The lower electrode LE3 is electrically connected to the pixel circuit 1 of the subpixel SP3.

In the illustrated example, the planar size of the aperture AP1, the planar size of the aperture AP2, and the planar size of the aperture AP3 differ from each other. The planar size of the aperture AP1 is greater than the aperture AP2. The planar size of the aperture AP2 is greater than the aperture AP3. The magnitude relationship of the planar sizes of the apertures AP1, AP2, and AP3 is not limited to the illustrated example.

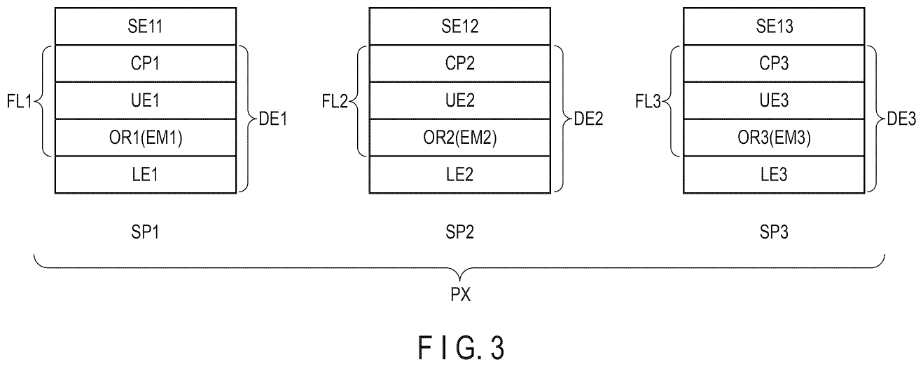

FIG. 3 is a view for describing an example of the pixel PX.

In the subpixel SP1, the display element DE1 comprises the lower electrode LE1, the organic layer OR1, the upper electrode UE1, and a cap layer CP1. The organic layer OR1 including a light emitting layer EM1 is provided between the lower electrode LE1 and the upper electrode UE1. The cap layer CP1 is provided on the upper electrode UE1. The sealing layer SE11 is provided on the cap layer CP1 and covers the display element DE1.

In the subpixel SP2, the display element DE2 comprises the lower electrode LE2, the organic layer OR2, the upper electrode UE2, and a cap layer CP2. The organic layer OR2 including a light emitting layer EM2 is provided between the lower electrode LE2 and the upper electrode UE2. The cap layer CP2 is provided on the upper electrode UE2. The sealing layer SE12 is provided on the cap layer CP2 and covers the display element DE2.

In the subpixel SP3, the display element DE3 comprises the lower electrode LE3, the organic layer OR3, the upper electrode UE3, and a cap layer CP3. The organic layer OR3 including a light emitting layer EM3 is provided between the lower electrode LE3 and the upper electrode UE3. The cap layer CP3 is provided on the upper electrode UE3. The sealing layer SE13 is provided on the cap layer CP3 and covers the display element DE3.

In the following explanation, a multilayer body including the organic layer OR1, the upper electrode UE1, and the cap layer CP1 may be called a stacked film FL1. A multilayer body including the organic layer OR2, the upper electrode UE2, and the cap layer CP2 may be called a stacked film FL2. A multilayer body including the organic layer OR3, the upper electrode UE3, and the cap layer CP3 may be called a stacked film FL3.

The light emitting layers EM1, EM2, and EM3 are formed of materials different from each other. For example, the light emitting layer EM1 is formed of a material that emits light in a blue wavelength range. The light emitting layer EM2 is formed of a material that emits light in a green wavelength range. The light emitting layer EM3 is formed of a material that emits light in a red wavelength range. That is, the display element DE1 is configured to display blue as the first color, the display element DE2 is configured to display green as the second color, and the display element DE3 is configured to display red as the third color.

The light emitting layer EM1 may be formed of a material that emits light in a green wavelength. The light emitting layer EM2 may be formed of a material that emits light in a blue wavelength. That is, the display element DE1 may be configured to display green as the first color, and the display element DE2 may be configured to display blue as the second color.

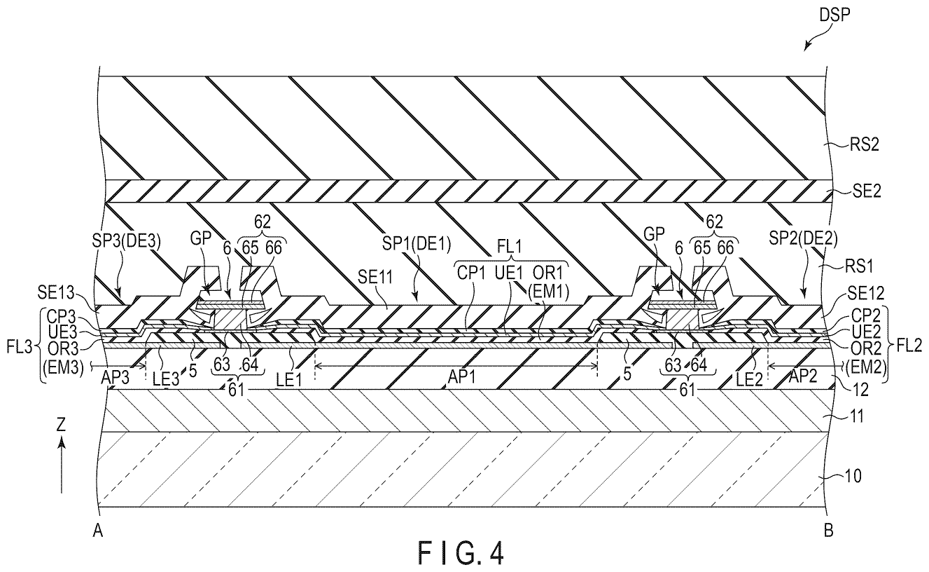

FIG. 4 is a schematic cross-sectional view of the display device DSP along the A-B line of FIG. 2.

A circuit layer 11 is provided on the substrate 10. The circuit layer 11 includes various circuits such as the pixel circuits 1 shown in FIG. 1, various lines such as the scanning line GL, the signal line SL, and the power line PL, and various insulating layers.

An organic insulating layer 12 is provided on the circuit layer 11. For example, the organic insulating layer 12 is formed to planarize irregularities formed by the circuit layer 11.

The lower electrode LE1 of the subpixel SP1, the lower electrode LE2 of the subpixel SP2, and the lower electrode LE3 of the subpixel SP3 are provided on the organic insulating layer 12 and are spaced apart from each other.

The inorganic insulating layer 5 is provided on the organic insulating layer 12 and the lower electrodes LE1, LE2, and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2, and LE3 are covered with the inorganic insulating layer 5. The lower electrodes LE1, LE2, and LE3 are connected to the pixel circuits 1 of the respective subpixels SP1, SP2, and SP3 through the contact holes provided in the organic insulating layer 12. The illustration of the contact holes in the organic insulating layer 12 is omitted.

The partition 6 is formed in an overhang shape and comprises a lower portion 61 having conductivity and provided on the inorganic insulating layer 5 and an upper portion 62 provided on the lower portion 61.

In the illustrated example, the lower portion 61 comprises a bottom layer 63 provided on the inorganic insulating layer 5 and a stem layer 64 provided between the bottom layer 63 and the upper portion 62. The bottom layer 63 is thinner than the stem layer 64. The bottom layer 63 has the width greater than the stem layer 64. Both end portions of the bottom layer 63 protrude relative to the side surfaces of the stem layer 64.

The upper portion 62 comprises a top layer 65 provided on the stem layer 64 and a cover layer 66 provided on the top layer 65. The top layer 65 and the cover layer 66 have widths greater than the stem layer 64. Both end portions of each of the top layer 65 and the cover layer 66 protrude relative to the side surfaces of the stem layer 64. In the present specification, the side surfaces of the stem layer 64 are assumed to be the side surfaces of the stem layer 64 that extend between the bottom layer 63 and the top layer 65. In the illustrated example, the upper portion 62 has the width greater than the bottom layer 63. The bottom layer 63 may have a width greater than the upper portion 62.

In the display element DE1, the organic layer OR1 contacts the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and contacts the lower portion 61.

In the display element DE2, the organic layer OR2 contacts the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and contacts the lower portion 61.

In the display element DE3, the organic layer OR3 contacts the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and contacts the lower portion 61.

The contact between each of the upper electrodes UE1, UE2, and UE3 and the lower portion 61 includes a case where each of the upper electrodes UE1, UE2, and UE3 directly contacts the upper surface of the bottom layer 63 and a case where each of the upper electrodes UE1, UE2, and UE3 directly contacts the upper surface of the bottom layer 63 and further directly contacts the side surfaces of the stem layer 64. In this specification, the upper surface of the bottom layer 63 is assumed to have, of the bottom layer 63, the surface that directly contacts the stem layer 64 and the surface that protrudes relative to the stem layer 64 and faces the upper portion 62.

The cap layer CP1 is provided on the upper electrode UE1. The cap layer CP2 is provided on the upper electrode UE2. The cap layer CP3 is provided on the upper electrode UE3. The cap layers CP1, CP2 and CP3 function as optical adjustment layers, which improve the extraction efficiency of light emitted from the respective organic layers OR1, OR2, and OR3. The cap layers CP1, CP2, and CP3 may be omitted.

The sealing layer SE11 is provided on the cap layer CP1, contacts the partition 6, and continuously covers each member of the subpixel SP1. The sealing layer SE11 contacts the stem layer 64 and the upper portion 62 of the partition 6 that surrounds the display element DE1.

The sealing layer SE12 is provided on the cap layer CP2, contacts the partition 6, and continuously covers each member of the subpixel SP2. The sealing layer SE12 contacts the stem layer 64 and the upper portion 62 of the partition 6 that surrounds the display element DE2.

The sealing layer SE13 is provided on the cap layer CP3, contacts the partition 6, and continuously covers each member of the subpixel SP3. The sealing layer SE13 contacts the stem layer 64 and the upper portion 62 of the partition 6 that surrounds the display element DE3.

Each of the sealing layers SE11, SE12, and SE13 extends above the partition 6. The edge portion of each of the sealing layers SE11, SE12, and SE13 is located above the partition 6.

None of the stacked films FL1, FL2, and FL3 are provided on the partition 6. Gaps GP are formed between the sealing layer SE11 and the partition 6, between the sealing layer SE12 and the partition 6, and between the sealing layer SE13 and the partition 6.

A transparent resin layer RS1 covers the partition 6 and the sealing layers SE11, SE12, and SE13. The resin layer RS1 fills each of the gaps GP formed between the sealing layer SE11 and the partition 6, between the sealing layer SE12 and the partition 6, and between the sealing layer SE13 and the partition 6.

The sealing layer SE2 covers the resin layer RS1. A transparent resin layer RS2 is provided on the sealing layer SE2.

Each of the inorganic insulating layer 5, the sealing layers SE11, SE12, and SE13 and the sealing layer SE2 is formed of, for example, an inorganic insulating material such as a silicon nitride (SiNx), a silicon oxide (SiOx), a silicon oxynitride (SiON) or an aluminum oxide (Al₂O₃). For example, the inorganic insulating layer 5 is formed of a silicon oxynitride, and each of the sealing layers SE11, SE12, SE13, and SE2 is formed of a silicon nitride.

The lower portion 61 of the partition 6 is formed of a conductive material and is electrically connected to the upper electrodes UE1, UE2 and UE3. The bottom layer 63 is formed of, for example, a titanium-based material such as titanium or a titanium compound. The bottom layer 63 may be formed of an oxide conductive material such as an indium tin oxide (ITO). The stem layer 64 is formed of a material different from the bottom layer 63 and the top layer 65, and is formed of, for example, an aluminum-based material such as aluminum or an aluminum compound.

The upper portion 62 of the partition 6 is formed of, for example, a conductive material. However, the upper portion 62 may be formed of an insulating material. In the illustrated example, the upper portion 62 is formed as a multilayer body of the top layer 65 and the cover layer 66, both of which are formed of conductive materials. The top layer 65 is formed of, for example, a titanium-based material such as titanium or a titanium compound. The cover layer 66 is formed of a material different from the top layer 65 and for example, formed of an oxide conductive material such as an ITO.

For example, each of the lower electrodes LE1, LE2, and LE3 is a multilayer body including an oxide conductive layer and a metal layer. The oxide conductive material is formed of an oxide conductive material such as an ITO. The metal layer is formed of a metal material such as silver and functions as a reflective layer. For example, each of the lower electrodes LE1, LE2, and LE3 is a multilayer body including a metal layer between a pair of oxide conductive layers.

The organic layer OR1 has the light emitting layer EM1. The organic layer OR2 has the light emitting layer EM2. The organic layer OR3 has the light emitting layer EM3. Each of the organic layers OR1, OR2, and OR3 has a plurality of functional layers such as a hole injection layer, a hole transport layer, an electron blocking layer, a hole blocking layer, an electron transport layer, and an electron injection layer.

The upper electrodes UE1, UE2, and UE3 are formed of, for example, a metal material such as an alloy of magnesium and silver (MgAg).

Each of the cap layers CP1, CP2, and CP3 is a multilayer body consisting of a plurality of thin films. All of the thin films are transparent and have refractive indices different from each other.

The circuit layer 11, the organic insulating layer 12, the inorganic insulating layer 5, and the partition 6, which are illustrated, are provided across the display area DA and the surrounding area SA.

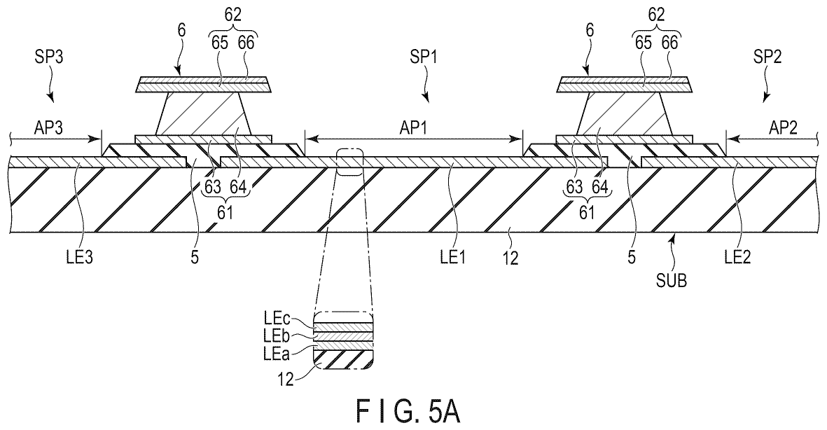

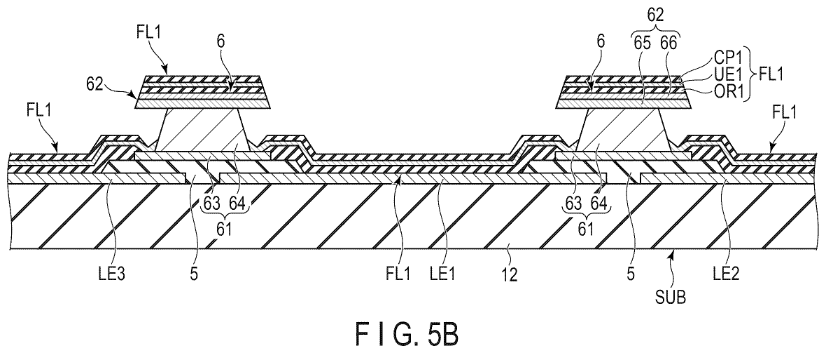

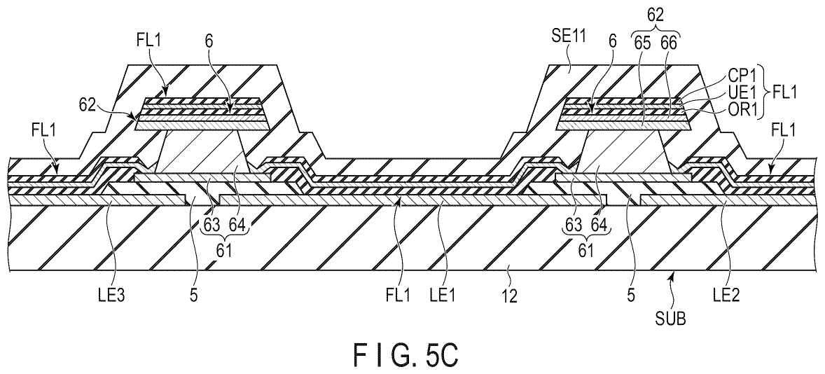

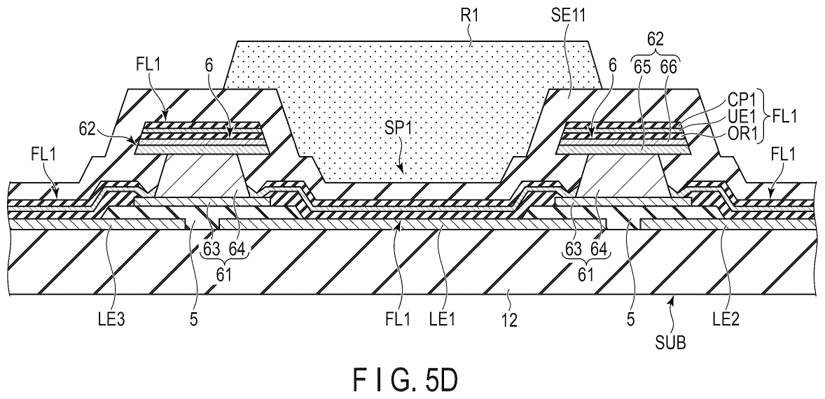

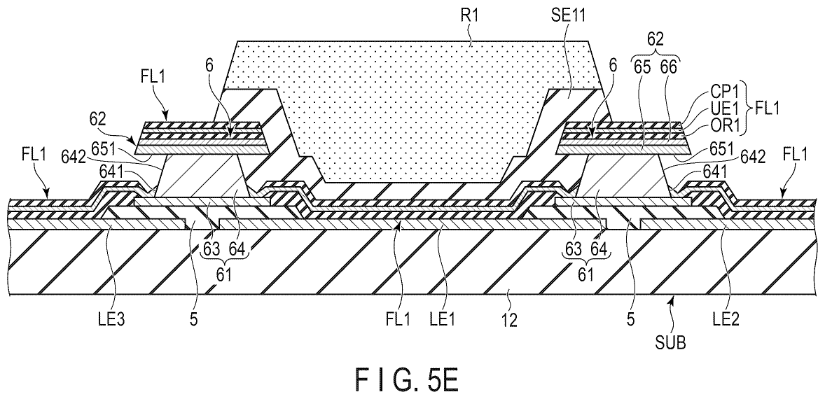

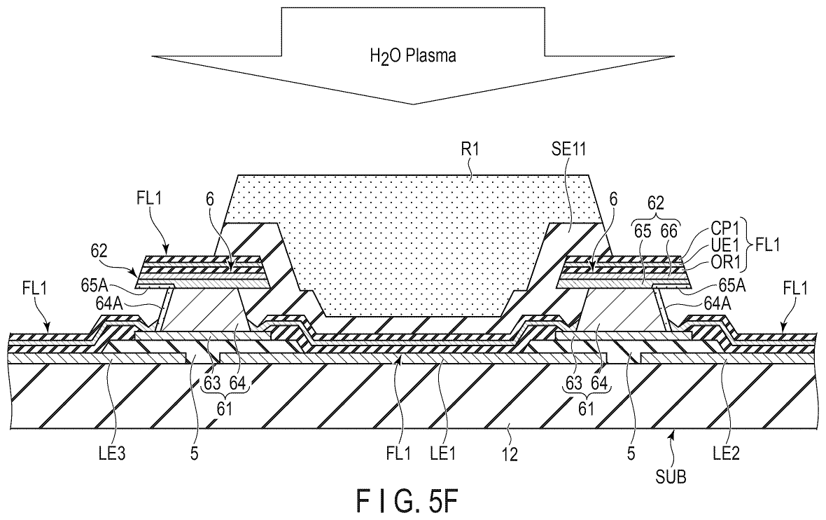

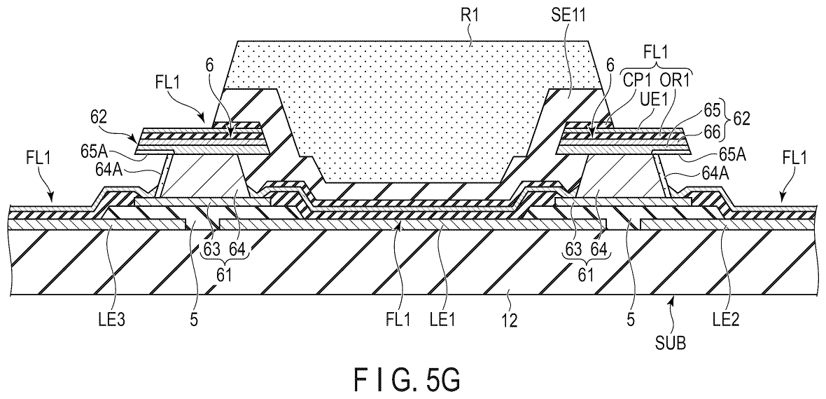

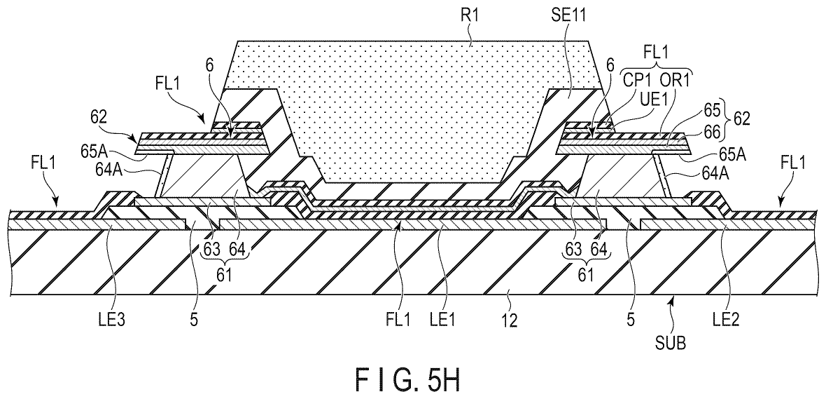

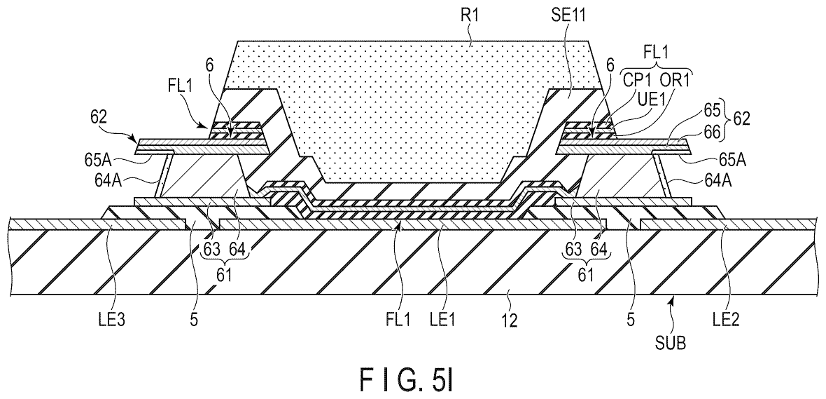

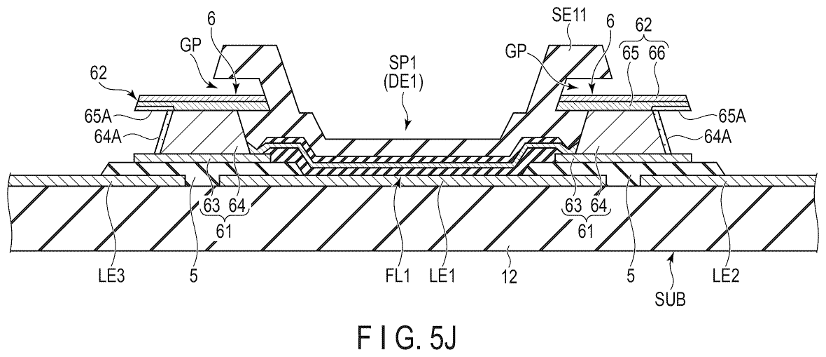

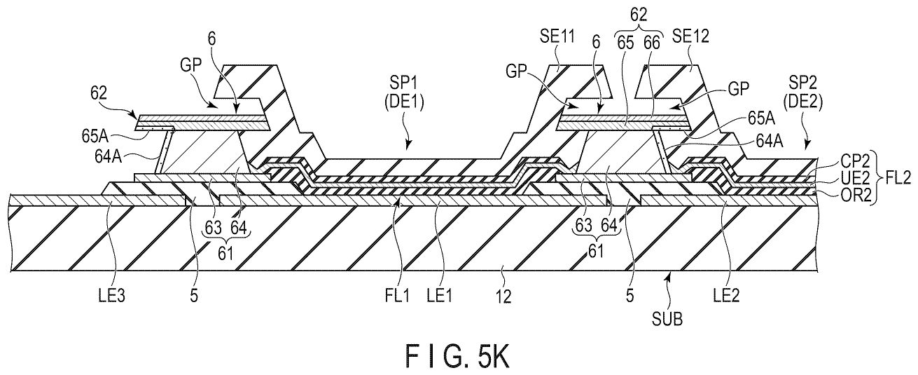

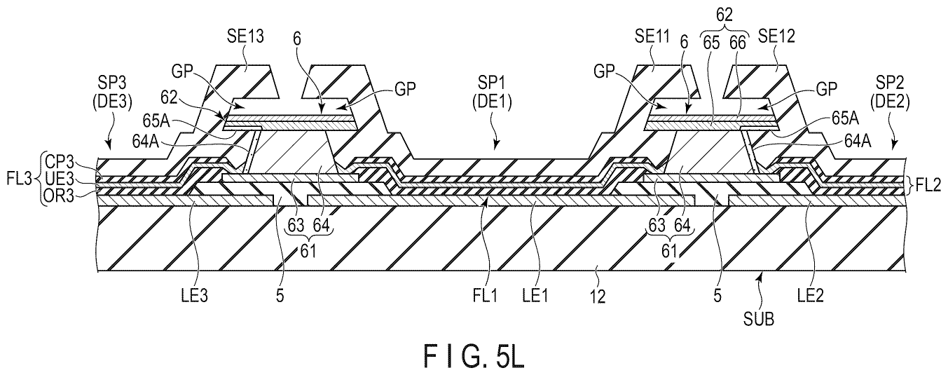

Next, the following will describe a manufacturing method of the display device DSP. FIG. 5A to FIG. 5L are cross-sectional views of the processing substrate SUB along the A-B line of FIG. 2 and omit the illustration of the elements below the organic insulating layer 12.

First, as shown in FIG. 5A, the processing substrate SUB is prepared. The process of preparing the processing substrate SUB includes a process of forming the lower electrode LE1 of the subpixel SP1, the lower electrode LE2 of the subpixel SP2, and the lower electrode LE3 of the subpixel SP3 on the organic insulating layer 12, a process of forming the inorganic insulating layer 5 having the apertures AP1, AP2, and AP3 overlapping the respective lower electrodes LE1, LE2, and LE3, and a process of forming the partition 6 having an overhang shape, surrounding each of the lower electrodes LE1, LE2, and LE3, and located on the inorganic insulating layer 5. The partition 6 may be formed after the formation of the inorganic insulating layer 5 having the apertures AP1, AP2, and AP3. Alternatively, the apertures AP1, AP2, and AP3 may be formed in the inorganic insulating layer 5 after the formation of the partition 6.

The process of forming the lower electrodes LE1, LE2, and LE3 includes a process of forming an oxide conductive layer LEa located on the organic insulating layer 12, a process of forming a metal layer LEb located on the oxide conductive layer LEa, and a process of forming an oxide conductive layer LEc of each of the lower electrodes LE1, LE2, and LE3. For example, after the formation of a stacked layer body including the oxide conductive layer LEa, the metal layer LEb, and the oxide conductive layer LEc, these layers are patterned all at once to form the lower electrodes LE1, LE2, and LE3.

The process of forming the partition 6 includes a process of forming the bottom layer 63 located on the inorganic insulating layer 5 of a conductive material, a process of forming the stem layer 64 located on the bottom layer 63 of an aluminum-based material, a process of forming the top layer 65 located on the stem layer 64 of a titanium-based material, and a process of forming the cover layer 66 located on the top layer 65 of an oxide conductive material. For example, the bottom layer 63 is formed of a titanium-based material, but may be formed of an oxide conductive material. This process of forming the partition 6 forms the bottom layer 63, the top layer 65, and the cover layer 66 such that they protrude relative to the side surfaces of the stem layer 64.

Subsequently, the display element DE1 is formed.

First, as shown in FIG. 5B, vapor deposition using the partition 6 as a mask is performed to form the stacked film FL1 on the processing substrate SUB. The stacked film FL1 is formed on the lower electrodes LE1, LE2, and LE3 and the partition 6. The stacked film FL1 includes the organic layer OR1 including the light emitting layer EM1, the upper electrode UE1, and the cap layer CP1. The organic layer OR1, the upper electrode UE1, and the cap layer CP1 are successively formed by an evaporation device in a vacuum state.

The stacked film FL1 is divided by the partition 6 having an overhang shape. That is, parts located on the lower electrodes LE1, LE2, and LE3 of the stacked film FL1 are spaced apart from parts located on the partition 6 of the stacked film FL1.

Subsequently, as shown in FIG. 5C, the sealing layer SE11 is formed on the stacked film FL1. The sealing layer SE11 is formed to continuously cover the stacked film FL1 and the partition 6. The sealing layer SE11 is formed by depositing inorganic insulating materials (for example, a silicon nitride) on the processing substrate SUB in a Chemical Vapor Deposition (CVD) device.

The stacked film FL1 and the sealing layer SE11 are substantially formed in the entire processing substrate SUB and are provided in the subpixels SP2 and SP3 as well as the subpixel SP1 in the display area DA.

Subsequently, as shown in FIG. 5D, a resist R1 patterned into a predetermined shape is formed on the sealing layer SE11. The resist R1 overlaps the subpixel SP1 and a part of the partition 6 around the subpixel SP1.

Subsequently, as shown in FIG. 5E, the sealing layer SE11 is patterned using the resist R1 as a mask. For example, dry etching is performed to remove the sealing layer SE11 exposed from the resist R1. Thus, the stacked film FL1 overlapping the lower electrode LE2 and the stacked film FL1 overlapping the lower electrode LE3 are exposed. Further, a part of the stacked film FL1 on the partition 6 is exposed. Further, a part of the partition 6 surrounding the lower electrode LE2 and a part of the partition 6 surrounding the lower electrode LE3 are exposed.

Here, the stacked film FL1 covers the bottom layer 63 on the partition 6 and covers a first portion 641, which is a part that connects to the bottom layer 63, of the side surfaces of the stem layer 64. In the illustrated example, the first portion 641 is covered with the upper electrode UE1 of the stacked film FL1. Further, the stacked film FL1 exposes the second portion 642 connecting to the top layer 65 of the side surfaces of the stem layer 64 and the lower surface 651 protruding with respect to the stem layer 64 of the top layer 65. The second portion 642 and the lower surface 651 are covered with the sealing layer SE11 before performing the dry etching shown in FIG. 5E.

Subsequently, as shown in FIG. 5F, water plasma (H₂0 plasma) treatment is performed on the processing substrate SUB. The water plasma treatment has high removal capability for organic matters and high oxidation capability for conductive materials. Thus, reaction products and fragments of the resist R1 having adhered to the processing substrate SUB in the dry etching shown in FIG. 5E are decomposed and removed in the water plasma treatment. Thus, the entire surface of the substrate SUB is purified. Further, the water plasma treatment oxidizes a part of the stem layer 64 formed of a metal material, forming an aluminum oxide film 64A as an oxide film on the side surface of the stem layer 64. Further, the water plasma treatment oxidizes a part of the top layer 65 formed of a metal material, forming a titanium oxide film 65A as an oxide film on the lower surface of the top layer 65.

In the illustrated example, the aluminum oxide film 64A is formed over the entire side surface, i.e., the entire area between the bottom layer 63 and the top layer 65, of the stem layer 64 of the partition 6 surrounding each of the lower electrodes LE2 and LE3. That is, both of the first portion 641 and the second portion 642 described with reference to FIG. 5E are oxidized. Thus, the aluminum oxide film 64A is formed on the first portion 641 and the second portion 642. At this time, a part protruding relative to the side surface of the stem layer 64 of the bottom layer 63 is covered with the stacked film FL1. Thus, this covered part is not oxidized in the water plasma treatment.

Subsequently, as shown in FIG. 5G, the cap layer CP1 of the stacked film FL1 is patterned using the resist R1 as a mask. Thus, the cap layer CP1 exposed from the resist R1 is removed. Thus, the upper electrode UE1 is exposed. If the cap layer CP1 includes an organic layer, at least a part of the cap layer CP1 may be removed in the water plasma treatment shown in FIG. 5F.

Subsequently, as shown in FIG. 5H, the upper electrode UE1 of the stacked film FL1 is patterned using the resist R1 as a mask. Thus, the upper electrode UE1 exposed from the resist R1 is removed. Thus, the organic layer OR1 is exposed. In the wet etching to remove the upper electrode UE1, the aluminum oxide film 64A functions as an etching stopper to suppress erosion of the stem layer 64 by the etchant. Similarly, the titanium oxide film 65A also functions as an etching stopper to suppress erosion of the top layer 65 by the etchant.

Subsequently, as shown in FIG. 5I, the organic layer OR1 of the stacked film FL1 is patterned using the resist R1 as a mask. Thus, the organic layer OR1 exposed from the resist R1 is removed. Further, a part of the partition 6, the lower electrode LE2, and the lower electrode LE3 are exposed.

Subsequently, as shown in FIG. 5J, the resist R1 is removed. For example, the process of removing the resist R1 includes a process of removing the resist R1 by stripper, and washing the processing substrate SUB with water. Thus, the display element DE1 is formed in the subpixel SP1. Further, the stacked film FL1 remaining between the partition 6 and the sealing layer SE11 is removed in the processes between the patterning of the stacked film FL1 and the removal of the resist R1. Thus, the gap GP is formed between the partition 6 and the sealing layer SE11. Further, the aluminum oxide film 64A and the titanium oxide film 65A function as etching stoppers against alkaline solution generated in the removal process of the resist R1, protecting the stem layer 64 and the top layer 65.

Subsequently, as shown in FIG. 5K, the display element DE2 is formed. The procedure of forming the display element DE2 is the same as that of forming the display element DE1. Thus, illustration of this procedure is omitted.

That is, the stacked film FL2 is formed on the lower electrode LE2. The stacked film FL2 includes the organic layer OR2 including the light emitting layer EM2, the upper electrode UE2, and the cap layer CP2. Subsequently, the sealing layer SE12 is formed on the stacked film FL2. Subsequently, a resist R2 is formed on the sealing layer SE12. Subsequently, the sealing layer SE12 and the stacked film FL2 are patterned using this resist R2 as a mask. After removing the sealing layer SE12 exposed from the resist R2 by this patterning, the cap layer CP2, the upper electrode UE2, and the organic layer OR2 included in the stacked film FL2 are removed in series. Subsequently, the resist R2 is removed.

Thus, the display element DE2 is formed in the subpixel SP2. Thus, the lower electrode LE3 of the subpixel SP3 is exposed. Further, the stacked film FL2 formed between the partition 6 and the sealing layer SE12 is removed in the processes between the patterning of the stacked film FL2 and the removal of the resist R2. Thus, the gap GP is formed between the partition 6 and the sealing layer SE12.

In the display element DE2, the aluminum oxide film 64A is formed on the side surface of the stem layer 64, and the titanium oxide film 65A is formed on the lower surface protruding relative to the side surface of the stem layer 64 of the top layer 65. The sealing layer SE12 contacts the aluminum oxide film 64A and the titanium oxide film 65A.

Subsequently, as shown in FIG. 5L, the display element DE3 is formed. The procedure of forming the display element DE3 is the same as that of forming the display element DE1. Thus, illustration of this procedure is omitted.

That is, the stacked film FL3 is formed on the lower electrode LE3. The stacked film FL3 includes the organic layer OR3 including the light emitting layer EM3, the upper electrode UE3, and the cap layer CP3. Subsequently, the sealing layer SE13 is formed on the stacked film FL3. Thereafter, a resist R3 is formed on the sealing layer SE13. Subsequently, the sealing layer SE12 and the stacked film FL2 are patterned using this resist R3 as a mask. After removing the sealing layer SE13 exposed from the resist R3 by this patterning, the cap layer CP3, the upper electrode UE3, and the organic layer OR3 included in the stacked film FL3 are removed in series. Subsequently, the resist R3 is removed.

Thus, the display element DE3 is formed in the subpixel SP3. Further, the stacked film FL3 formed between the partition 6 and the sealing layer SE13 is removed in the processes between the patterning of the stacked film FL3 and the removal of the resist R3. Thus, the gap GP is formed between the partition 6 and the sealing layer SE13.

In the display element DE3, the aluminum oxide film 64A is formed on the side surface of the stem layer 64, and the titanium oxide film 65A is formed on the lower surface protruding relative to the side surface of the stem layer 64 of the top layer 65. The sealing layer SE13 contacts the aluminum oxide film 64A and the titanium oxide film 65A.

The above-described manufacturing process assumes a case where the display element DE1 is formed firstly, and the display element DE2 is formed secondly, and the display element DE3 is formed lastly. However, the formation order of the display elements DE1, DE2, and DE3 is not limited to this example.

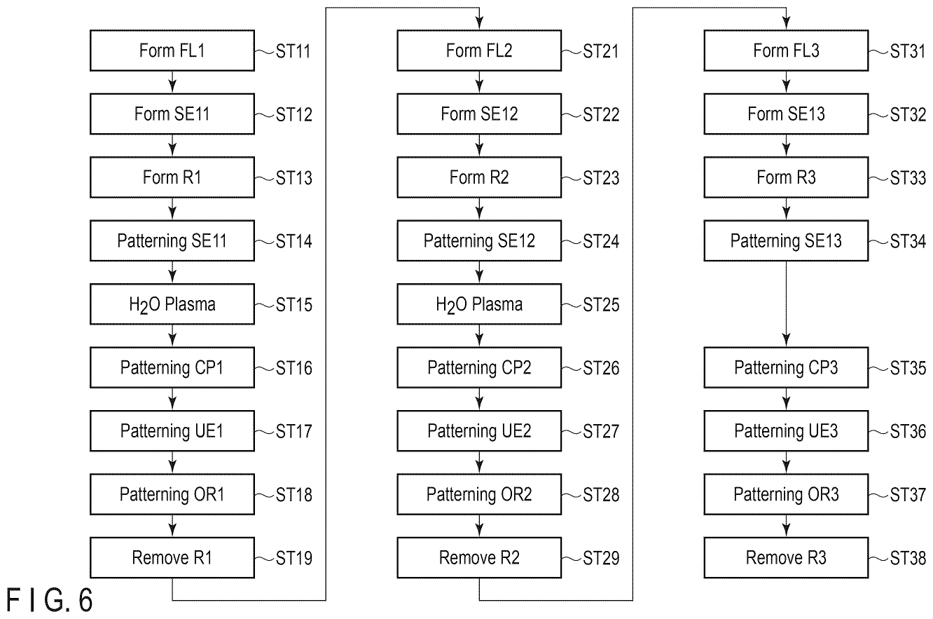

FIG. 6 is a diagram for describing main steps for forming display elements DE1, DE2, and DE3 on the processing substrate SUB.

First, vapor deposition using the partition 6 as a mask is performed to form the stacked film FL1 on the lower electrodes LE1, LE2, and LE3 and the partition 6 (the step ST11). Then, the sealing layer SE11 is formed on the stacked film FL1 (the step ST12). Subsequently, the resist R1 is formed on the sealing layer SE11(the step ST13). Then, the sealing layer SE11 is patterned using the resist R1 as a mask (the step ST14).

Thereafter, the water plasma (H₂0 plasma) treatment is performed on the substrate SUB (the step ST15).

Then, the stacked film FL1 is patterned using the resist R1 as a mask. First, the cap layer CP1 is patterned (the step ST16). Then, the upper electrode UE1 is patterned (the step ST17). Thereafter, the organic layer OR1 is patterned (the step ST18). Subsequently, the resist R1 is removed (the step ST19). Thus, the display element DE1 is formed.

Subsequently, vapor deposition using the partition 6 as a mask is performed to form the stacked film FL2 on the sealing layer SE11, the lower electrode LE2, and the lower electrode LE3 and the partition 6 of the display element DE1 (the step ST21). Then, the sealing layer SE12 is formed on the stacked film FL2 (the step ST22). Subsequently, the resist R2 is formed on the sealing layer SE12 (the step ST23). Then, the sealing layer SE12 is patterned using the resist R2 as a mask (the step ST24).

Thereafter, the water plasma (H₂0 plasma) treatment is performed on the substrate SUB (the step ST25). If the water plasma treatment in the step ST15 has formed the oxide films 64A and 65A that have sufficient thicknesses, the water plasma treatment in the step ST25 may be omitted.

Then, the stacked film FL2 is patterned using the resist R2 as a mask. First, the cap layer CP2 is patterned (the step ST26). Then, the upper electrode UE2 is patterned (the step ST27). Thereafter, the organic layer OR2 is patterned (the step ST28). Subsequently, the resist R2 is removed (the step ST29). Thus, the display element DE2 is formed.

Subsequently, vapor deposition using the partition 6 as a mask is performed to form the stacked film FL3 on the sealing layer SE11 of the display element DE1, the sealing layer SE21, the lower electrode LE3, and the partition 6 of the display element DE2 (the step ST31). Then, the sealing layer SE13 is formed on the stacked film FL3 (the step ST32). Subsequently, the resist R3 is formed on the sealing layer SE13 (the step ST33). Then, the sealing layer SE13 is patterned using the resist R3 as a mask (the step ST34).

Thereafter, the stacked film FL3 is patterned using the resist R3 as a mask without performing the water plasma treatment on the processing substrate SUB. First, the cap layer CP3 is patterned (the step ST35). Then, the upper electrode UE3 is patterned (the step ST36). Thereafter, the organic layer OR3 is patterned (the step ST37). Subsequently, the resist R3 is removed (the step ST38). Thus, the display element DE3 is formed.

Then, an organic insulating material is applied and cured on the sealing layers SE11, SE12, and SE13, forming the resin layer RS1 shown in FIG. 4. At this time, the applied organic insulating material fills the gaps GP formed between the partition 6 and the sealing layer SE11, between the partition 6 and the sealing layer SE12, and between the partition 6 and the sealing layer SE13.

Then, the sealing layer SE2 is formed by depositing an inorganic insulating material (for example, a silicon nitride). Then, an organic insulating material is applied and cured. Thus, the resin layer RS2 is formed.

The display device DSP is completed through these processes.

As described above, in the process of forming the display element DE1, the water plasma treatment is performed at the timing after patterning the sealing layer SE11 and before patterning the upper electrode UE1. Thus, undesirable reaction products having adhered to the side surfaces of the stem layer 64 are removed, and an oxide film is formed on the side surfaces of the stem layer 64. Thus, the oxide film can suppress erosion of the stem layer 64 to maintain the partition 6 in its desired shape in the following patterning processes and the removal processes of the resist. Thus, emission failures of the display elements caused by instability of the shape of partition 6 can be prevented. Thus, decreases in the reliability can be suppressed.

Further, the sealing layers SE11, SE12, and SE13 reliably seal the respective display elements DE1, DE2, and DE3. Thus, the moisture intrusion to the display elements can be suppressed.

Furthermore, oxidation of the bottom layer 63 is suppressed in the formation of the oxide film in the water plasma treatment. Thus, reliable electrical connection is achieved between the bottom layer 63 and the upper electrodes UE2 and UE3.

The following will describe another manufacturing method. In the following descriptions on a manufacturing method, steps overlapping those of the above manufacturing method may be omitted.

First, as shown in FIG. 5A, the processing substrate SUB is prepared. Then, as shown in FIG. 5B, the stacked film FL1 is formed. Thereafter, as shown in FIG. 5C, the sealing layer SE11 is formed. Subsequently, as shown in FIG. 5D, the resist R1 is formed. Subsequently, as shown in FIG. 5E, the sealing layer SE11 is patterned. At this time, the stacked film FL1 covers the bottom layer 63 and also covers the first portion 641 of the stem layer 64. Further, the stacked film FL1 exposes the second portion 642 of the stem layer 64 and the lower surface 651 protruding with respect to the stem layer 64 of the top layer 65.

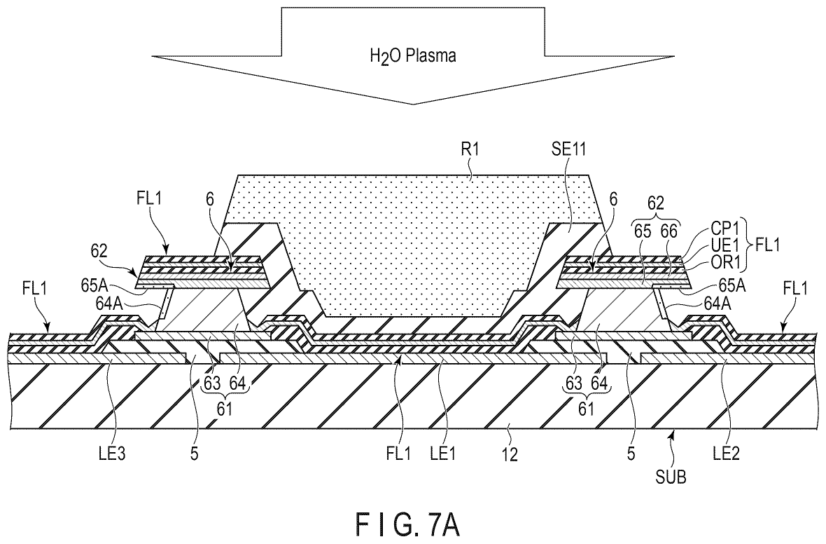

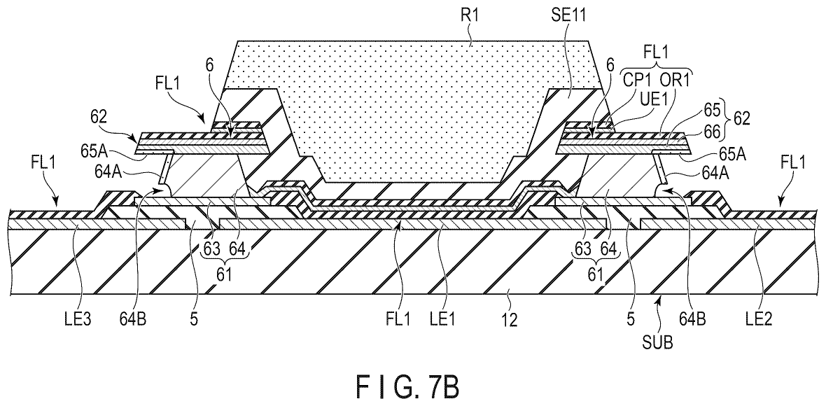

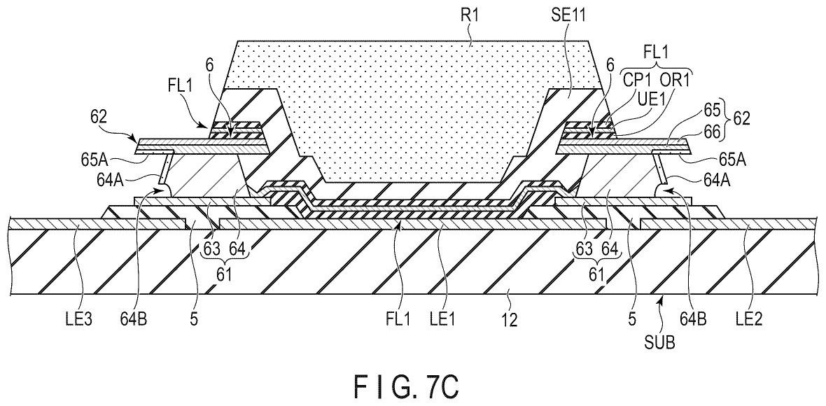

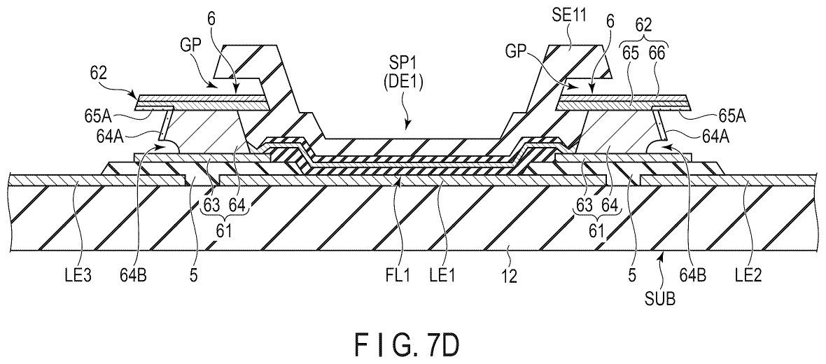

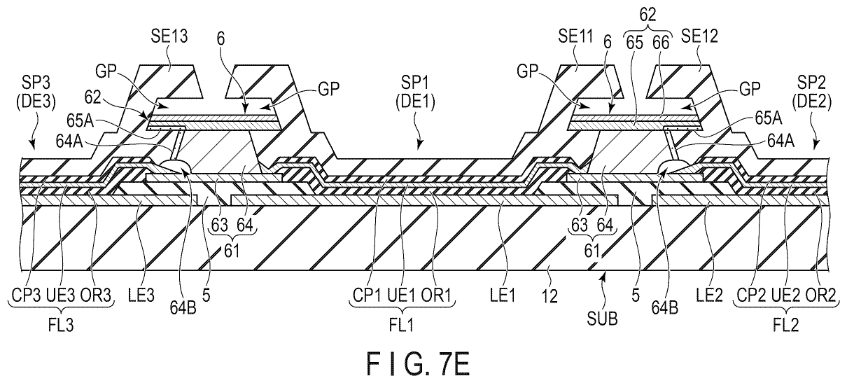

Subsequently, as shown in FIG. 7A, the water plasma (H₂0 plasma) treatment is performed on the processing substrate SUB. This water plasma treatment forms the aluminum oxide film 64A as an oxide film on the second portion 642 on the stem layer 64 of the partition 6, which surrounds the lower electrodes LE2 and the lower electrode LE3. Further, on the top layer 65, the titanium oxide film 65A is formed as an oxide film on the lower surface protruding with respect to the side of the stem layer 64.

In contrast, the first portion 641 covered with the stacked film FL1 is not oxidized. The area that is oxidized of the stem layer 64 in the water plasma treatment shown here is smaller than the one in the water plasma treatment shown in FIG. 5F. The area that is oxidized of the stem layer 64 can be controlled by adjusting process conditions such as processing time and pulse power.

Subsequently, as shown in FIG. 7B, after patterning the cap layer CP1 of the stacked film FL1 using the resist R1 as a mask, the upper electrode UE1 is patterned. Thus, the upper electrode UE1 exposed from the resist R1 is removed and the first portion 641 of the partition 6 surrounding the lower electrodes LE2 and LE3 is removed. Thus, a cavity 64B is formed in the stem layer 64. Further, the bottom layer 63 is exposed in the cavity 64B. The aluminum oxide film 64A and the titanium oxide film 65A remain.

Subsequently, as shown in FIG. 7C, the organic layer OR1 of the stacked film FL1 is patterned using the resist R1 as a mask. Thus, the organic layer OR1 exposed from the resist R1 is removed. Further, a part of the partition 6, the lower electrode LE2, and the lower electrode LE3 are exposed.

Subsequently, as shown in FIG. 7D, the resist R1 is removed. Thus, the display element DE1 is formed in the subpixel SP1. Further, the stacked film FL1 remaining between the partition 6 and the sealing layer SE11 is removed in the processes between the patterning of the stacked film FL1 and the removal of the resist R1. Thus, the gap GP is formed between the partition 6 and the sealing layer SE11. Furthermore, a part not covered by the aluminum oxide film 64A of the stem layers 64 dissolves due to the alkaline solution generated in the removal process of the resist R1. Thus, the cavity 64B is expanded.

Subsequently, as shown in FIG. 7E, the display element DE3 is formed after the formation of the display element DE2.

In the display element DE2, the aluminum oxide film 64A formed on the side surface of the stem layer 64 and the titanium oxide film 65A formed on the lower surface of the top layer 65 contact the sealing layer SE12.

With respect to the partition 6 located between the display elements DE1 and DE2, the stem layer 64 has the cavity 64B recessed with respect to the side surface surrounding the display element DE2. Further, the bottom layer 63 is exposed in the cavity 64B. In contrast, the stem layer 64 does not have a cavity recessed with respect to the side surface surrounding the display element DE1.

The upper electrode UE2 extends toward the cavity 64B and contacts the bottom layer 63. The upper electrode UE2 does not contact the side surface of the stem layer 64. In contrast, the upper electrode UE1 contacts the bottom layer 63 protruding with respect to the stem layer 64. The contact area of the upper electrode UE2 and the bottom layer 63 is greater than the contact area of the upper electrode UE1 and the bottom layer 63.

In the display element DE3, the aluminum oxide film 64A formed on the side surface of the stem layer 64 and the titanium oxide film 65A formed on the lower surface of the top layer 65 contact the sealing layer SE13.

With respect to the partition 6 located between the display elements DE1 and DE3, the stem layer 64 has the cavity 64B recessed with respect to the side surface surrounding the display element DE3. Further, the bottom layer 63 is exposed in the cavity 64B. In contrast, the stem layer 64 does not have a cavity recessed with respect to the side surface surrounding the display element DE1.

The upper electrode UE3 extends toward the cavity 64B and contacts the bottom layer 63. The upper electrode UE3 does not contact the side surface of the stem layer 64. In contrast, the upper electrode UE1 contacts the bottom layer 63 protruding with respect to the stem layer 64. The contact area of the upper electrode UE3 and the bottom layer 63 is greater than the contact area of the upper electrode UE1 and the bottom layer 63.

Thus, the connection resistance is reduced between the upper electrode UE2 of the display element DE2, formed after the display element DE1, and the partition 6. Further, the connection resistance is reduced between the upper electrode UE3 of the display element DE3 and the partition 6.

Furthermore, from the perspective of reducing damage to the bottom layer 63 made exposed between the patterning of the stacked film FL1 and the removal of the resist R1, the bottom layer 63 may be formed of an oxide conductive material such as an ITO.

In the manufacturing methods described with reference to FIG. 5A to FIG. 5L and the manufacturing methods described with reference to FIG. 7A to FIG. 7E, an additional water plasma treatment may be performed at the timing after patterning the upper electrode UE1 and before patterning the organic layer OR1. Further, an additional water plasma treatment may be performed at the timing after patterning the organic layer OR1 and before forming the stacked film FL2.

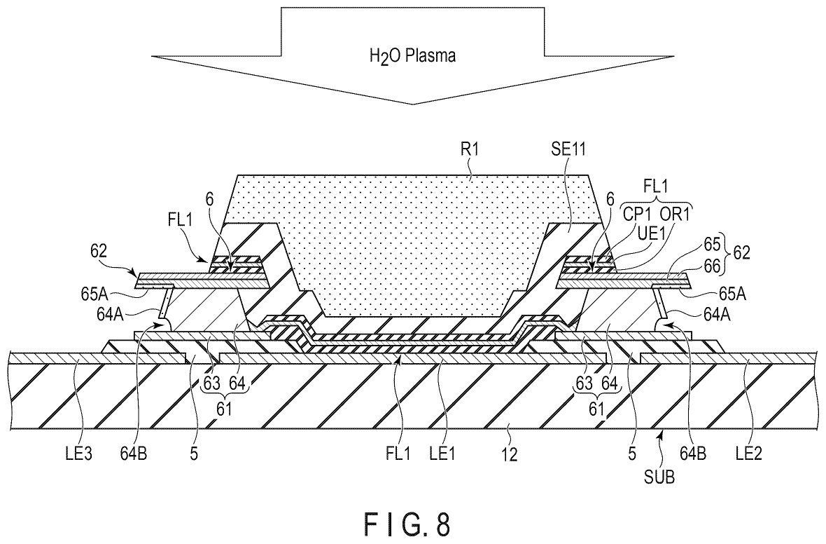

In the example shown in FIG. 8, an additional water plasma (H₂0 plasma) treatment is performed at the timing after patterning the organic layer OR1 (in other words, after patterning the stacked film FL1) and before removing the resist R1. This additional water plasma treatment oxidizes the oxide conductive layer located on the surface of the lower electrodes LE2 and LE3 and the cover layer 66 (the oxide conductive layer) of the partition 6 and fosters the crystallization. Thus, the hole injection efficiency from the lower electrodes LE2 and LE3 is improved in the display elements DE2 and DE3. Further, the strength of the upper portion 62 is improved on the partition 6 as well.

In the above embodiment, for example, the display element DE1 corresponds to the first display element. The display element DE2 corresponds to the second display element. The third display element DE3 corresponds to the third display element.

The lower electrode LE1 corresponds to the first lower electrode. The lower electrode LE2 corresponds to the second lower electrode. The lower electrode LE3 corresponds to the third lower electrode. The organic layer OR1 corresponds to the first organic layer. The organic layer OR2 corresponds to the second organic layer. The organic layer OR3 corresponds to the third organic layer. The light emitting layer EM1 corresponds to the first light emitting layer. The light emitting layer EM2 corresponds to the second light emitting layer. The light emitting layer EM3 corresponds to the third light emitting layer. The upper electrode UE1 corresponds to the first upper electrode. The upper electrode UE2 corresponds to the second upper electrode. The upper electrode UE3 corresponds to the third upper electrode. The cap layer CP1 corresponds to the first cap layer. The cap layer CP2 corresponds to the second cap layer. The cap layer CP3 corresponds to the third cap layer.

The stacked film FL1 corresponds to the first stacked film. The stacked film FL2 corresponds to the second stacked film. The stacked film FL3 corresponds to the third stacked film. The sealing layer SE11 corresponds to the first sealing layer. The sealing layer SE12 corresponds to the second sealing layer. The sealing layer SE13 corresponds to the third sealing layer. The resist R1 corresponds to the first resist. The resist R2 corresponds to the second resist. The resist R3 corresponds to the third resist.

As explained above, the present embodiment can provide a display device capable of suppressing decreases in reliability and a manufacturing method of the display device.

All of the display devices and manufacturing methods thereof that can be implemented by a person of ordinary skill in the art through arbitrary design changes to the display device and manufacturing method thereof disclosed above as each embodiment of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is

1. A manufacturing method of a display device, the method comprising steps of:
preparing a processing substrate by forming a first lower electrode, a second lower electrode, and a third lower electrode above a substrate, and forming a partition having an overhang shape and surrounding each of the first lower electrode, the second lower electrode, and the third lower electrode;
forming a first stacked film including a first organic layer, a first upper electrode, and a first cap layer above the first lower electrode, the second lower electrode, and the third lower electrode using the partition as a mask;
forming a first sealing layer on the first stacked film, and covering the partition with the first sealing layer,
forming a first resist patterned into a predetermined shape on the first sealing layer;
patterning the first sealing layer using the first resist as a mask to expose a part of the partition surrounding each of the second lower electrode and the third lower electrode;
performing water plasma treatment on the processing substrate;
patterning the first stacked film using the first resist as a mask to expose the second lower electrode and the third lower electrode; and
removing the first resist.

2. The manufacturing method of claim 1, wherein
the step of forming the partition includes a step of forming a stem layer of an aluminum-based material, and
the water plasma treatment forms an aluminum oxide film on a side surface of the stem layer.

3. The manufacturing method of claim 2, wherein
the step of forming the partition includes a step of forming a top layer of a titanium-based material,
the top layer is located on the stem layer and has a lower surface protruding with respect to the side surface of the stem layer, and
the water plasma treatment forms a titanium oxide film on the lower surface.

4. The manufacturing method of claim 1, wherein
the step of preparing the processing substrate includes a step of forming an inorganic insulating layer having respective apertures overlapping the first lower electrode, the second lower electrode, and the third lower electrode, after forming the first lower electrode, the second lower electrode, and the third lower electrode, and
the step of forming the partition includes:
a step of forming a bottom layer located on the inorganic insulating layer;
a step of forming a stem layer located on the bottom layer; and
a step of forming the top layer located on the stem layer, and
the bottom layer and the top layer are formed to protrude with respect to a side surface of the stem layer.

5. The manufacturing method of claim 4, wherein
the water plasma treatment forms an oxide film on the entire side surface of the partition surrounding each of the second lower electrode and the third lower electrode.

6. The manufacturing method of claim 4, wherein
the first stacked film covers the bottom layer and a first portion connecting to the bottom layer of the side surface of the stem layer and exposes a second portion connecting to the top layer of the side surface, and
the water plasma treatment forms an oxide film on the second portion of the partition surrounding each of the second lower electrode and the third lower electrode.

7. The manufacturing method of claim 6, wherein
the step of patterning the first stacked film includes a step of removing the first upper electrode exposed from the first resist, and
in the step of removing the first upper electrode removes,
the first portion of the partition surrounding each of the second lower electrode and the third lower electrode is removed,
a cavity is formed in the stem layer, and
the bottom layer is exposed in the cavity.

8. The display device manufacturing method of claim 7, wherein
in the step of removing the first resist, the cavity expands.

9. The manufacturing method of claim 4, wherein
the bottom layer is formed of an oxide conductive material.

10. The manufacturing method of claim 1, wherein
the step of forming the first lower electrode, the second lower electrode, and the third lower electrode includes a step of forming an oxide conductive layer located on a surface of each of the first lower electrode, the second lower electrode, and the third lower electrode, and
further comprising step of:
a process of performing the water plasma treatment after patterning the first stacked film.

11. The manufacturing method of claim 1, further comprising steps of:
forming a second sealing layer including a second organic layer, a second upper electrode, and a second cap layer and located on the second lower electrode;
forming a second sealing layer located on the second stacked film; and
performing the water plasma treatment on the processing substrate after patterning the second sealing layer.

12. The manufacturing method of claim 11, further comprising steps of:
forming a third stacked layer including a third organic layer, a third upper electrode, and a third cap layer and located on the third lower electrode;
forming a third sealing layer located on the third stacked film; and
patterning the third stacked film after patterning the third sealing layer without performing the water plasma treatment on the processing substrate.

13. A display device, comprising:
a substrate;
an inorganic insulating layer provided above the substrate;
a first display element configured to display a first color;
a second display element configured to display a second color different from the first color;
a third display element configured to display a third color different from the first color and the second color;
a partition formed in an overhang shape, provided on the inorganic insulating layer, having conductivity, and surrounding each of the first display element, the second display element, and the third display element;
a first sealing layer covering the first display element;
a second sealing layer covering the second display element; and
a third sealing layer covering the third display element, wherein
the partition comprises a bottom layer provided on the inorganic insulating layer, a stem layer provided on the bottom layer, and a top layer provided on the stem layer,
both end portions of each of the bottom layer and the top layer protrude relative to side surfaces of the stem layer,
the stem layer has a cavity recessing with respect to the side surfaces surrounding each of the second display element and the third display element, and
the bottom layer is exposed in the cavity.

14. The display device of claim 13, wherein
the stem layer does not have a cavity recessed with respect to the side surface surrounding the first display element.

15. The display device of claim 13, wherein
the second display element comprises a second upper electrode electrically connected to the partition,
the third display element comprises a third upper electrode electrically connected to the partition, and
each of the second upper electrode and the third upper electrode extends toward the cavity.

16. The display device of claim 13, wherein
the first display element comprises a first upper electrode electrically connected to the partition,
the second display element comprises a second upper electrode electrically connected to the partition, and
a contact area of the second upper electrode and the bottom layer is greater than a contact area of the first upper electrode and the bottom layer.

17. The display device of claim 16, wherein
the third display element comprises a third upper electrode electrically connected to the partition, and
a contact area of the third upper electrode and the bottom layer is greater than the contact area of the first upper electrode and the bottom layer.

18. The display device of claim 13, wherein
the stem layer is formed of an aluminum-based material and has an oxide aluminum film on the side surfaces surrounding each of the second display element and the third display element.

19. The display device of claim 18, wherein
the top layer is formed of a titanium-based material and has a titanium oxide film on a lower surface protruding with respect to the side surfaces of the stem layer.

20. The display device of claim 19, wherein
each of the second sealing layer and the third sealing layer contacts the aluminum oxide film and the titanium oxide film.
